(19) United States
(12) Patent Application Publication
(10) Pub. No.: US 2024/0332165 A1
(43) Pub. Date: Oct. 3, 2024

(54) OFFSET VIA FORMATION FOR FLEXIBLE ROUTING

(71) Applicant: International Business Machines Corporation, Armonk, NY (US)

(72) Inventors: Ruilong Xie, Niskayuna, NY (US); Nicholas Anthony Lanzillo, Wynantskill, NY (US); Huai Huang, Clifton Park, NY (US); Atharv Jog, Albany, NY (US); Hosadurga Shobha, Niskayuna, NY (US); Lawrence A. Clevenger, Saratoga Springs, NY (US)

(21) Appl. No.: 18/126,591

(22) Filed: Mar. 27, 2023

(51) Int. Cl. H01L 23/522; H01L 21/768; H01L 23/528

(52) U.S. Cl. CPC H01L 23/5226; H01L 21/76805; H01L 21/76831; H01L 23/528; H01L 21/76843

(57) ABSTRACT

A semiconductor interconnect structure and formation thereof. The semiconductor interconnect structure includes a plurality of metal lines of a first metal level. The semiconductor interconnect structure further includes a via formed substantially offset from a centerline of a first metal line and at least partially through a first portion of the first metal line located beneath the via.

### BACKGROUND

The present disclosure generally relates to fabrication methods and structures for semiconductor devices, and more specifically, to the formation of vias that are offset from underlying lines to allow for flexible routing in the back-end-of-the-line (BEOL) structure of an integrated circuit (IC).

An integrated circuit (IC) may be formed with millions of transistors and other circuit elements that are fabricated on a single silicon crystal substrate (wafer). For the IC to be functional, multi-level or multi-layered interconnection schemes such as, for example, metal wiring formed by single damascene processes, dual damascene processes, subtractive patterning (i.e., subtractive etch processes), and combinations thereof, are fabricated in the back-end-of-the-line (BEOL) of the device to connect the circuit elements distributed in the front-end-of-the-line (FEOL) of the device. Connections between interconnect levels, called vias, allow signals and power to be transmitted between one level to the next.

### SUMMARY

According to one embodiment of the present invention, a semiconductor interconnect structure is provided. The semiconductor interconnect structure includes a plurality of metal lines of a first metal level. The semiconductor interconnect structure further includes a via formed substantially offset from a centerline of a first metal line and at least partially through a first portion of the first metal line located beneath the via.

According to another embodiment of the present invention, a semiconductor interconnect structure is provided. The semiconductor interconnect structure includes a plurality of metal lines of a first metal level. The semiconductor interconnect structure further includes a first via formed substantially over a centerline of a first metal line of the plurality of metal lines located beneath the first via. The semiconductor interconnect structure further includes a second via formed substantially offset from a centerline of a second metal line of the plurality of metal lines located beneath the second via.

According to another embodiment of the present invention, a semiconductor interconnect structure is provided. The semiconductor interconnect structure includes a plurality of metal lines of a first metal level. The semiconductor interconnect structure further includes a first via formed substantially offset from a centerline of a first metal line of the plurality of metal lines located beneath the first via. The semiconductor interconnect structure further includes a second via formed substantially offset from a centerline of a second metal line of the plurality of metal lines located beneath the second via.

### BRIEF DESCRIPTION OF THE SEVERAL VIEWS OF THE DRAWINGS

FIG. 1A illustrates a top view of an initial semiconductor interconnect structure, generally designated 100, in accordance with at least one embodiment of the present invention.

FIG. 1B illustrates a cross-sectional view of semiconductor structure 100 taken along line 1B, in accordance with at least one embodiment of the present invention.

FIG. 1C illustrates a cross-sectional view of semiconductor structure 100 taken along line 1C, in accordance with at least one embodiment of the present invention.

FIG. 2A illustrates a top view of semiconductor structure 100 after performing subsequent processing steps, generally designated 200, in accordance with at least one embodiment of the present invention.

FIG. 2B illustrates a cross-sectional view of semiconductor structure 200 taken along line 1B, in accordance with at least one embodiment of the present invention.

FIG. 2C illustrates a cross-sectional view of semiconductor structure 200 taken along line 2C, in accordance with at least one embodiment of the present invention.

FIG. 3A illustrates a top view of semiconductor structure 200 after performing subsequent processing steps, generally designated 300, in accordance with at least one embodiment of the present invention.

FIG. 3B illustrates a cross-sectional view of semiconductor structure 300 taken along line 3B, in accordance with at least one embodiment of the present invention.

FIG. 3C illustrates a cross-sectional view of semiconductor structure 300 taken along line 3C, in accordance with at least one embodiment of the present invention.

FIG. 4A illustrates a top view of semiconductor structure 300 after performing subsequent processing steps, generally designated 400, in accordance with at least one embodiment of the present invention.

FIG. 4B illustrates a cross-sectional view of semiconductor structure 400 taken along line 4B, in accordance with at least one embodiment of the present invention.

FIG. 4C illustrates a cross-sectional view of semiconductor structure 400 taken along line 4C, in accordance with at least one embodiment of the present invention.

FIG. 5A illustrates a top view of semiconductor structure 400 after performing subsequent processing steps, generally designated 500, in accordance with at least one embodiment of the present invention.

FIG. 5B illustrates a cross-sectional view of semiconductor structure 500 taken along line 5B, in accordance with at least one embodiment of the present invention.

FIG. 5C illustrates a cross-sectional view of semiconductor structure 500 taken along line 5C, in accordance with at least one embodiment of the present invention.

FIG. 6A illustrates a top view of semiconductor structure 500 after performing subsequent processing steps, generally designated 600, in accordance with at least one embodiment of the present invention.

FIG. 6B illustrates a cross-sectional view of semiconductor structure 600 taken along line 6B, in accordance with at least one embodiment of the present invention.

FIG. 6C illustrates a cross-sectional view of semiconductor structure 600 taken along line 6C, in accordance with at least one embodiment of the present invention.

FIG. 7A illustrates a top view of an alternate embodiment of semiconductor structure 600 after performing subsequent processing steps, generally designated 700, in accordance with at least one embodiment of the present invention.

FIG. 7B illustrates a cross-sectional view of semiconductor structure 700 taken along line 6B, in accordance with at least one embodiment of the present invention.

FIG. 7C illustrates a cross-sectional view of semiconductor structure 700 taken along line 7C, in accordance with at least one embodiment of the present invention.

FIG. 8A illustrates a top view of an alternate embodiment of semiconductor structure 600 of FIG. 6, generally designated 800, in accordance with at least one embodiment of the present invention.

FIG. 8B illustrates a cross-sectional view of semiconductor structure 800 taken along line 8B, in accordance with at least one embodiment of the present invention.

FIG. 8C illustrates a cross-sectional view of semiconductor structure 800 taken along line 8C, in accordance with at least one embodiment of the present invention.

FIG. 8D illustrates a cross-sectional view of semiconductor structure 800 taken along line 8D, in accordance with at least one embodiment of the present invention.

FIG. 9A illustrates a top view of semiconductor structure 600 after performing subsequent processing steps, generally designated 900, in accordance with at least one embodiment of the present invention.

FIG. 9B illustrates a cross-sectional view of semiconductor structure 900 taken along line 9B, in accordance with at least one embodiment of the present invention.

FIG. 10A illustrates a top view of semiconductor structure 700 after performing subsequent processing steps, generally designated 1000, in accordance with at least one embodiment of the present invention.

FIG. 10B illustrates a cross-sectional view of semiconductor structure 1000 taken along line 10B, in accordance with at least one embodiment of the present invention.

FIG. 11 is flowchart diagram depicting a method 1100 of fabricating a semiconductor interconnect structure corresponding to the semiconductor structures described with reference to FIGS. 1A-1C . . . 7A-7C, 8A-8D, and 9A-9B . . . 10A-10B, in accordance with at least one embodiment of the present invention.

### DETAILED DESCRIPTION

In conventional back-end-of-the-line (BEOL) metal wiring schemes, vias are typically formed on top of and aligned with underlying metal lines in order to maximize overlap and thereby reduce contact resistance. Furthermore, vias formed on top of adjacent lower level metal lines are typically staggered to avoid tip-to-tip (T2T) failure between overlying upper level metal lines. However, embodiments of the present invention recognize that this particular via arrangement limits via routing possibilities and BEOL design flexibility as whole.

Embodiments of the present invention provide for improved via routing and BEOL design flexibility by increasing the T2T space between upper level metal lines connected to adjacent lower metal lines by vias that are at least partially aligned with one another along the line direction. According to an embodiment of the present invention, a first via opening is formed on top of a first lower level metal line and arranged such that a centerline of the first via opening is substantially aligned with a centerline of the first lower level metal line. A second via opening is formed such that it at least partially extends, in a vertical direction, through respective portions of a pair of adjacent lower level metal lines, in which one of the lines in the pair is also located adjacent to the first lower level metal line. The second via opening is further formed such that a centerline of the second via opening is located between, and substantially offset from respective centerlines of the pair of adjacent lower level metal lines. An inner spacer is formed within the second via opening. A first portion of the inner spacer formed within the second via opening that is in contact with one of the lower level metal lines in the pair of adjacent lower level metal lines is removed, such that a second portion of the inner spacer formed within the second via opening that is in contact with the other lower line in the pair of adjacent metal lines is retained. Finally, a metallization process is performed within the first and second via openings to form first and second vias, respectively.

By forming a via that is offset from a centerline of a lower level metal line, the routing flexibility of vias is expanded to allow for vias that are connected to adjacent lower level metal lines that are at least partially aligned with one another along the line direction. To compensate for the loss of surface contact due to the via being offset from the underlying metal line, the offset via is formed at least partially through, rather than on top of the underlying metal line, thereby increasing the surface contact between the via and underlying metal line, while the use of the inner spacer formed within a portion of the via ensures that the via is only in contact with a single underlying metal line.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of microcooler device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, exposure to a specific frequency or range of frequencies of electromagnetic radiation, ion implantation techniques, and/or chemical/mechanical polishing (CMP). As used herein, terms, such as “forming,” and the like, may refer to processes that alter the structure of one or more layers of material, or portions of material(s), by removal of a quantity of material, in accordance with a given embodiment. For example, such formation processes may include, but are not limited to, micromachining, microetching, wet and/or dry etching processes, plasma etching processes, or any of the known etching processes in which material is removed.

As used herein, the terms “metal level,” “metal layer,” “interconnect level,” and “interconnect layer” may be used interchangeably and may refer to one of a plurality of metal wiring levels in the BEOL of an integrated circuit (IC).

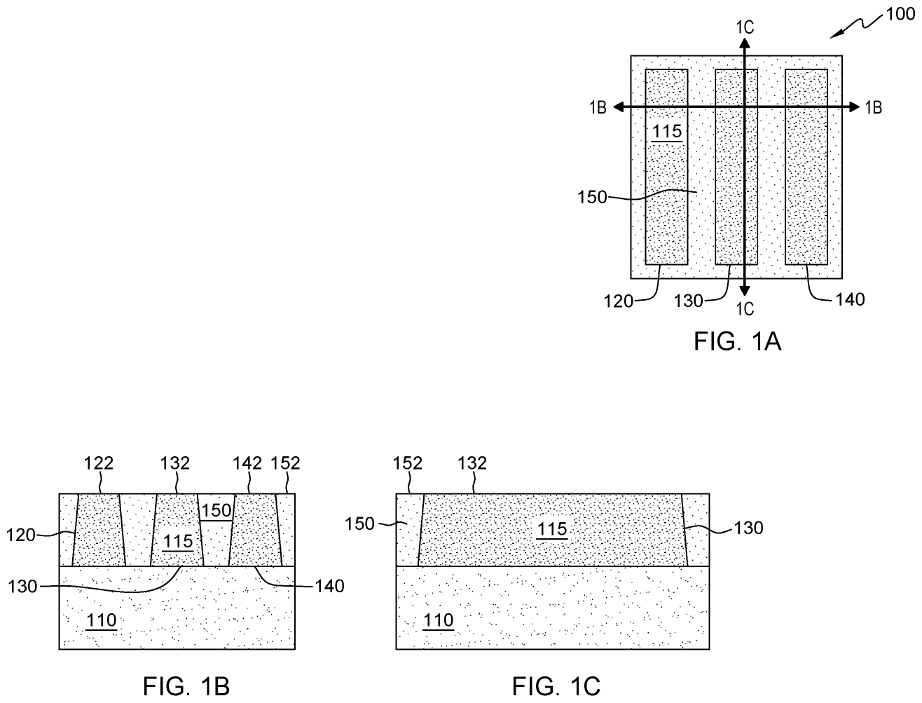

The present invention will now be described in detail with reference to the Figures. FIGS. 1A-1C . . . 7A-7C, 8A-8D, and 9A-9B . . . 10A-10B include various views depicting illustrative steps of a method for manufacturing semiconductor interconnect structures and the resulting semiconductor interconnect structures according to select embodiments of the present invention. One having ordinary skill in the art will appreciate that there are many options available for the formation of the structures described herein and that the following discussion does not limit embodiments to only the techniques described herein.

FIGS. 1A-1C illustrate a top view and corresponding cross-sectional views of an initial semiconductor structure 100, in accordance with at least one embodiment of the present invention. Referring to the top view of FIG. 1A and the cross-sectional views of FIGS. 1B, 1C taken along corresponding lines 1B, 1C, lines 120, 130, 140 are formed on a substrate 110. In some embodiments, and as depicted in FIGS. 1A-1C, lines 120, 130, 140 are representative of a first set of metal lines of a first metal wiring level.

In some embodiments, substrate 110 may be part of a front-end-of-the-line (FEOL) structure. A FEOL structure is typically present beneath the lowest level of the multilayered interconnect structure and includes a semiconductor substrate having one or more semiconductor devices such as, for example, transistors, capacitors, resistors, and etc. located thereon. In other embodiments, substrate 110 may include one or more interconnect levels of a multilayered interconnect structure, such as a back-end-of-the-line (BEOL) structure. A BEOL structure is typically where the individual semiconductor devices in the FEOL structure are interconnected with one another. In such embodiments, each interconnect level (i.e., metal level) may include one or more electrically conductive structures embedded in an interconnect dielectric material. For example, the one or more interconnect levels of a multilayer interconnect structure may be formed from any generally known semiconductor materials, such as silicon, gallium arsenide, or germanium.

In some embodiments, and as depicted in FIGS. 1A-1C, substrate 110 may be a bulk semiconductor wafer, such as a bulk silicon (Si), bulk germanium (Ge), bulk silicon germanium (SiGe) and/or bulk III-V semiconductor wafer. Alternatively, in other embodiments, substrate 110 is a semiconductor-on-insulator (SOI) wafer. A SOI wafter includes a SOI layer separated from a substrate by a buried insulator. When the buried insulator is an oxide, it is referred to herein as a buried oxide or BOX. The SOI layer can include any suitable semiconductor, such as Si, Ge, SiGe, and/or a III-V semiconductor.

In assembly of semiconductor structure 100, a conductive metal layer 115 is formed by depositing a conductive metal material (e.g., via atomic layer deposition (ALD), chemical vapor deposition (CVD), plasma enhanced CVD (PECVD), or any other suitable deposition techniques) onto the top surface of substrate 110. In an embodiment, the conductive metal material may be a metal or metal alloy including, but not limited to, aluminum (Al), ruthenium (Ru), rhodium (Rh), iridium (Ir), tungsten (W), molybdenum (Mo), nickel (Ni), or an alloy thereof.

Next, one or more subtractive etch processes are performed to pattern conductive metal layer 115 to form metal lines 120, 130, 140. For example, a mask layer (not depicted) is formed by depositing an inorganic hard mask material (e.g., silicon nitride, titanium nitride, tantalum nitride, or any suitable inorganic metal-containing material) or an organic soft mask material (e.g., carbon, hydrogen, oxygen, and optionally nitrogen, fluorine, and silicon) an organic material such as onto the top surface of conductive metal layer 115. The hard mask layer can be formed utilizing a deposition process including, but not limited to, CVD, PECVD, ALD, physical vapor deposition (PVD) or sputtering.

A photoresist material (not depicted) is then deposited onto the surface of the mask layer. The photoresist material can be applied by any suitable techniques, including, but not limited to, coating or spin-on techniques. A photomask (not depicted) patterned with shapes defining metal lines 120, 130, 140 to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the mask layer. Dry etch techniques (for example, an anisotropic etch process, such as reactive ion etch) may be employed to selectively remove portions of the mask layer to form the patterned mask. After formation of patterned mask, the photoresist material may be stripped from the patterned hard mask by ashing or other suitable processes. The resulting structure may be subjected to a wet clean.

During patterning of conductive metal layer 115 using the patterned mask, the physically exposed portions of conductive metal layer 115 are removed by an anisotropic etching process such as, for example, reactive ion etching (RIE), ion beam etching (IBE), chemical wet etching, or a combination of IBE and chemical wet etching. The etch removes the exposed portions of conductive metal layer 115 that are not protected by the patterned mask to form metal lines 120, 130, 140.

After patterning conductive metal layer 115 to form metal lines 120, 130, 140, an interlayer dielectric (ILD) material is conformally deposited onto the patterned conductive metal layer 115 to form ILD layer 150. ILD layer 150 may be composed of an inorganic dielectric material or an organic dielectric material. In some embodiments, ILD layer 150 may be porous. In other embodiments, ILD layer 150 may be non-porous. In some embodiments, ILD layer 150 may have a dielectric constant (all dielectric constants mentioned herein are measured relative to a vacuum, unless otherwise stated) that is about 4.0 or less. In an embodiment, ILD layer 150 may have a dielectric constant of 2.8 or less. These dielectrics having a dielectric constant of 2.8 or less generally have a lower parasitic cross talk as compared to dielectric materials whose dielectric constant is greater than 4.0. Examples of suitable dielectric materials that may be employed as ILD layer 150 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

A planarization process such as, for example, chemical mechanical planarization or polishing (CMP) and/or grinding, may subsequently be performed to remove portions of ILD layer 150 present above top surfaces 122, 132, 142 of lines 120, 130, 140. The planarization stops when top surface 152 of ILD layer 150 is substantially coplanar with top surfaces 122, 132, 142 of lines 120, 130, 140.

It should be appreciated that although metal lines 120, 130, 140 are described above as being formed by subtractive patterning of a metal or metal alloy, in other embodiments of the present invention, metal lines 120, 130, 140 may be formed using a single damascene or dual damascene process as known by one of ordinary skill in the art.

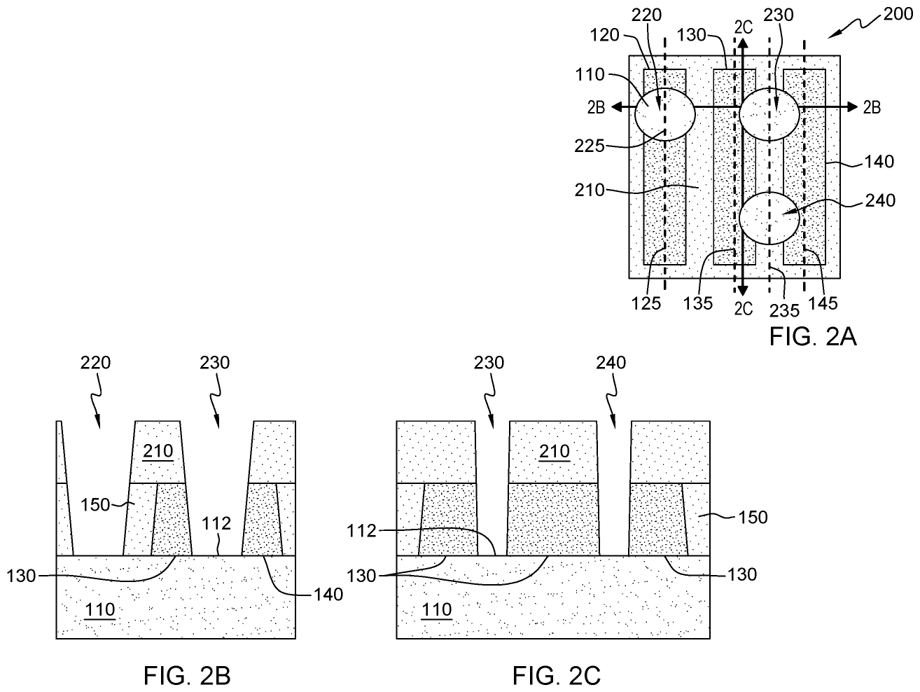

FIGS. 2A-2C illustrate a top view and corresponding cross-sectional views of semiconductor structure 100 depicted in FIGS. 1A-1C after performing subsequent processing steps, generally designated 200, in accordance with at least one embodiment of the present invention. In assembly of semiconductor structure 200, and referring to the top view of FIG. 2A and the cross-sectional views of FIGS. 2B, 2C taken along corresponding lines 2B, 2C, an interlayer dielectric (ILD) material is deposited onto the top surface of semiconductor structure 100 (depicted in FIGS. 1A-1C) to form ILD layer 210, followed by the formation of via openings 220, 230, 240 using one or more subtractive etch processes.

ILD layer 210 may be formed by depositing an ILD material using known techniques including, but not limited to, chemical vapor deposition (CVD), plasma enhanced chemical vapor deposition (PECVD), atomic layer deposition (ALD), physical vapor deposition (PVD), sputtering, or chemical solution deposition. In some embodiments, and as depicted in FIGS. 2A-2C, ILD layer 150 and ILD layer 210 are formed from the same material(s). In other embodiments, ILD layer 150 and ILD layer 210 may be formed from different materials.

Via openings 220, 230, 240 may be formed by patterning ILD layer 210, ILD layer 150, and metal lines 120, 130, 140 using a patterned mask (not depicted). For example, the patterned mask may be formed using the same processes and materials as described above with reference to FIGS. 1A-1C. In some embodiments, the patterned mask is a soft mask formed from an organic soft mask material. In other embodiments, the patterned mask is a hard mask formed from an inorganic hard mask material.

The patterned mask, which acts as an etch mask, is formed such that the portions of the underlying ILD layer 210, ILD layer 150, and metal lines 120, 130, 140 corresponding to via openings 220, 230, 240 to be formed are left exposed by the patterned mask, while the remaining portions of the underlying ILD layer 210, ILD layer 150, and metal lines 120, 130, 140 remain covered. Using the patterned hard mask, the physically exposed portions of ILD layer 210, ILD layer 150, and metal lines 120, 130, 140 are removed by an etching process such as, for example, reactive ion etching (RIE), ion beam etching (IBE), chemical wet etching, or a combination of IBE and chemical wet etching to form via openings 220, 230, 240. In some embodiments, and as depicted in FIGS. 2A-2C, via openings 220, 230, 240 are formed using an isotropic etching process. However, in other embodiments, via openings 220, 230, 240 may be formed using an anisotropic etching process.

As depicted by FIGS. 2A-2C, via openings 220, 230, 240 extend completely through ILD layer 210, ILD layer 150, and metal lines 120, 130, 140, such that a top surface 112 of substrate 110 is exposed. In some embodiments, although not depicted, via openings 220, 230, 240 may further extend at least partially through substrate 110 as well. In some embodiments, although not depicted, via openings 220, 230, 240 only partially extend through metal lines 120, 130, 140, such that top surface 112 of substrate remains covered. In some embodiments, although not depicted, at least one of vias 220, 230, 240 extends completely through one or more underlying metal lines, and at least one of vias 220, 230, 240 extends only partially through one or more underlying metal lines.

As depicted by FIG. 2A, via opening 220 has a centerline 225 that is aligned with a centerline 125 of metal line 120, while via openings 230, 240 have a centerline 235 that is located between, and offset from centerlines 135, 145 of metal lines 130, 140. As further depicted by FIG. 2A, via opening 220 extends through a single metal line (i.e., line 120), while via openings 230, 240 each extend through respective portions of a pair of adjacent metal lines (i.e., lines 130, 140). It should be appreciated that embodiments of the present invention are not limited to the particular arrangement of via openings 220, 230, 240 as depicted in FIGS. 2A-2C. Rather, embodiments of the present invention allow for the flexible routing of via openings (and the vias subsequently formed therein) beyond the conventional formation of via openings formed on top of and aligned with underlying metal lines.

In some embodiments, the particular degree of offset of a via centerline from an underlying metal line centerline can be increased or decreased based on the particular interconnect routing scheme. In some embodiments, the particular degree of offset of a via centerline from an underlying metal line centerline can be increased or decreased based on a minimum required pitch between a pair of adjacent vias located in the same via level that are at least partially aligned with one another in the line direction of the underlying metal lines. For example, the minimum required pitch between adjacent vias may be based on maintaining a minimum required tip to tip (T2T) space between two different metal lines of an upper metal level formed above respective adjacent vias that at least partially overlap in the line direction of the metal lines of a lower metal level. The minimum required T2T space may be based on the printing capabilities (in terms of line pitch and line width) and margin of error of the particular lithography technology used in semiconductor device fabrication to make integrated circuits (ICs).

In some embodiments, the particular degree of offset of a via centerline from an underlying metal line centerline can be increased or decreased based on an allowable amount of contact resistance between a via and an underlying lower level metal line. For example, as the degree of offset increases, the amount of surface contact between the sidewall of the via running through the underlying lower level metal line decreases, which ultimately results in greater contact resistance. Accordingly, a tradeoff may eventually occur between via routing flexibility and device performance.

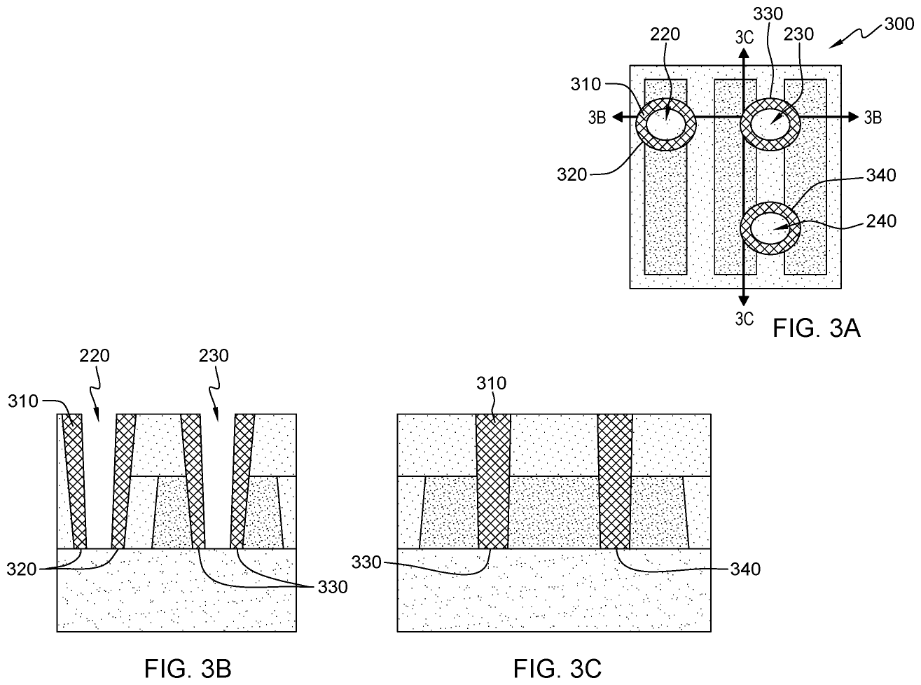

FIGS. 3A-3C illustrate a top view and corresponding cross-sectional views of semiconductor structure 200 depicted in FIGS. 2A-2C after performing subsequent processing steps, generally designated 300, in accordance with at least one embodiment of the present invention. In assembly of semiconductor structure 300, and referring to the top view of FIG. 3A and the cross-sectional views of FIGS. 3B, 3C taken along corresponding lines 3B, 3C, inner spacers 320, 330, 340 are formed within via openings 220, 230, 240.

Inner spacers 320, 330, 340 may be formed by depositing a spacer material 310 (e.g., via atomic layer deposition (ALD), chemical vapor deposition (CVD), plasma enhanced CVD (PECVD), or any other suitable deposition techniques) within via openings 220, 230, 240, followed by an anisotropic etch. In various embodiments, spacer material 310 may be composed of a dielectric material, including, but not limited to, silicon nitride (SiN), silicon carbide (SiC) carbonitride (SiCN), silicoboron carbonitride (SiBCN), silicon oxynitride (SiON), silicon oxcycarbonitride (SiOCN), or combinations thereof. The formation of inner spacers from such spacer materials are well understood by one of ordinary skill in the art and, as such, a more detailed description of such processes is not presented herein.

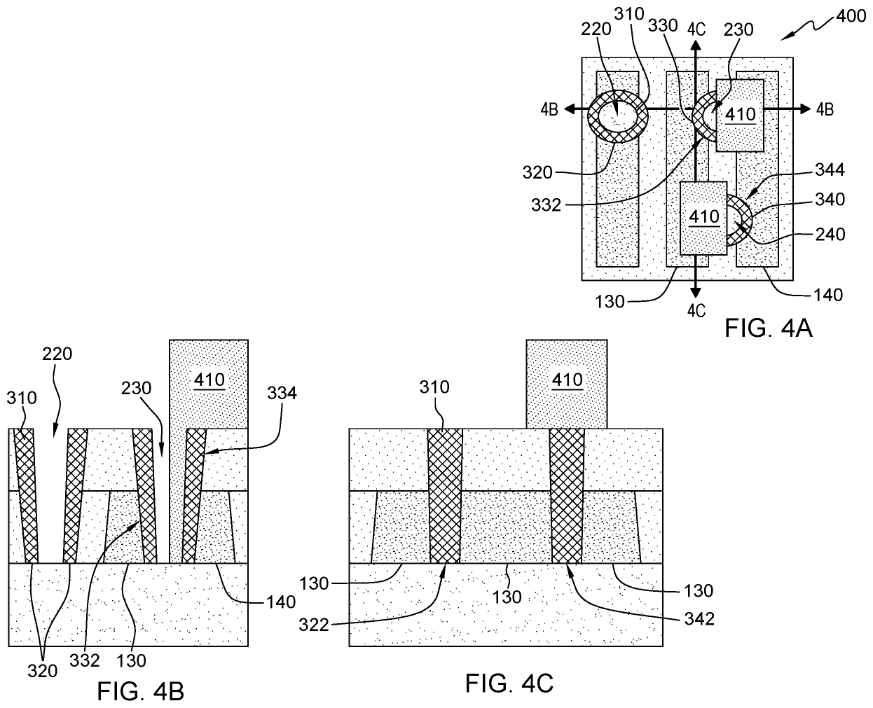

FIGS. 4A-4C illustrate a top view and corresponding cross-sectional views of semiconductor structure 300 depicted in FIGS. 3A-3C after performing subsequent processing steps, generally designated 400, in accordance with at least one embodiment of the present invention. In assembly of semiconductor structure 400, and referring to the top view of FIG. 4A and the cross-sectional views of FIGS. 4B, 4C taken along corresponding lines 4B, 4C, a mask material is deposited onto semiconductor structure 300 (depicted in FIGS. 3A-3C) to form a mask layer 410, followed by the patterning of mask layer 410.

Mask layer 410 may be formed by depositing a mask material using known techniques including, but not limited to, spin-on coating, chemical vapor deposition (CVD), plasma enhanced chemical vapor deposition (PECVD), atomic layer deposition (ALD), physical vapor deposition (PVD), sputtering, or chemical solution deposition. In some embodiments, and as depicted in FIGS. 4A-4C, mask layer 410 is a soft mask formed from an organic soft mask material. In other embodiments, mask layer 410 is a hard mask formed from an inorganic hard mask material.

As depicted, mask layer 410 has been patterned using, for example, the same processes and materials as described above with reference to FIGS. 1A-1C. The patterned mask layer 410, which acts as an etch mask, is formed such that the portions of the underlying spacer material 310 of inner spacers 320, 330, 340 to be retained is protected by the patterned mask layer 410, while the remaining portions of the underlying spacer material 310 of inner spacers 320, 330, 340 to be removed is left exposed. In various embodiments, the mask layer 410 is patterned based on the particular wiring scheme of the upper level metal lines to be formed. For example, if an upper level metal line is formed above and running in a direction perpendicular to metal lines 130, 140, and the wiring scheme requires that the upper level metal line only be connected to the lower level metal line 130, then mask layer 410 is patterned such that portion 334 of inner spacer 330 within via opening 230 that is in contact with metal line 140 is retained. Similarly, since the wiring scheme requires that the upper level metal line only be connected to the lower level metal line 140, then mask layer 410 would also be patterned such that portion 332 of inner spacer 330 within opening 230 that is in contact with metal line 130 be removed.

In another example, if an upper level metal line is formed above and running in a direction perpendicular to metal lines 130, 140, and the wiring scheme requires that the upper level metal line only be connected to the lower level metal line 130, then mask layer 410 is patterned such that portion 342 of inner spacer 340 within via opening 240 that is in contact with metal line 130 is retained. Similarly, since the wiring scheme requires that the upper level metal line only be connected to the lower level metal line 130, then mask layer 410 would also be patterned such that portion 344 of inner spacer 340 within via opening 240 that is in contact with metal line 140 be removed.

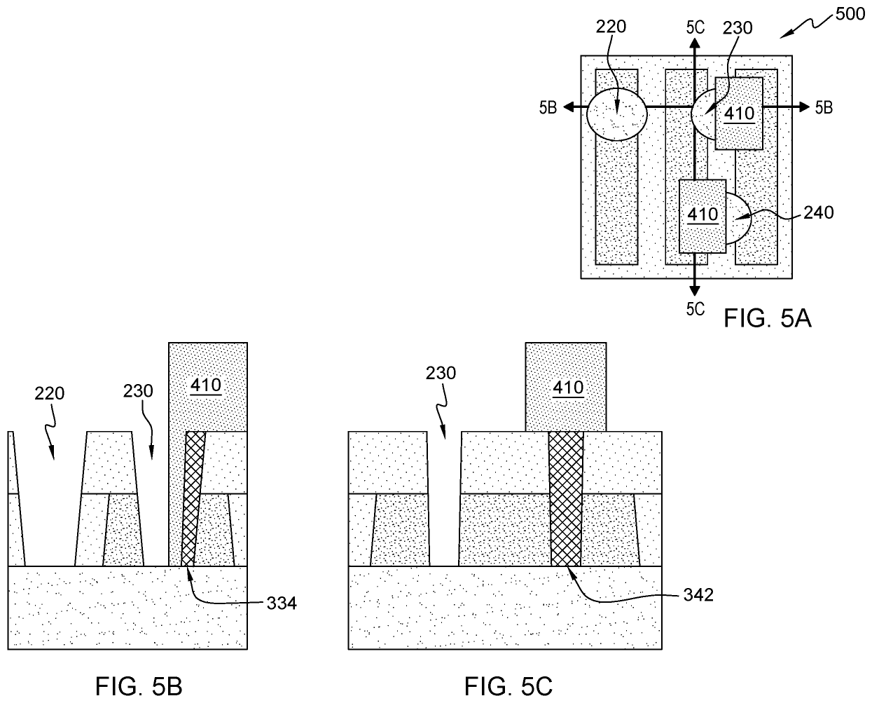

FIGS. 5A-5C illustrate a top view and corresponding cross-sectional views of semiconductor structure 400 depicted in FIGS. 4A-4C after performing subsequent processing steps, generally designated 500, in accordance with at least one embodiment of the present invention. In assembly of semiconductor structure 500, and referring to the top view of FIG. 5A and the cross-sectional views of FIGS. 5B-5C taken along corresponding lines 5B, 5C, portions 332, 344 of inner spacers 330, 340, (depicted in FIGS. 4A-4C) and all of inner spacer 320 (depicted in FIGS. 4A-4C) have been removed from via openings 220, 230, 240, while portions 334, 342 of inner spacers 330, 340 have been retained within via openings 230, 240. For example, portions 332, 344 of inner spacers 330, 340 and all of inner spacer 330 are removed using the patterned mask layer 410 and an etching process such as, for example, reactive ion etching (RIE), ion beam etching (IBE), chemical wet etching, or a combination of IBE and chemical wet etching. In some embodiments, and as depicted by FIGS. 5A-5C, an isotropic etching process has been used. However, in other embodiments, an anisotropic etching process may be employed.

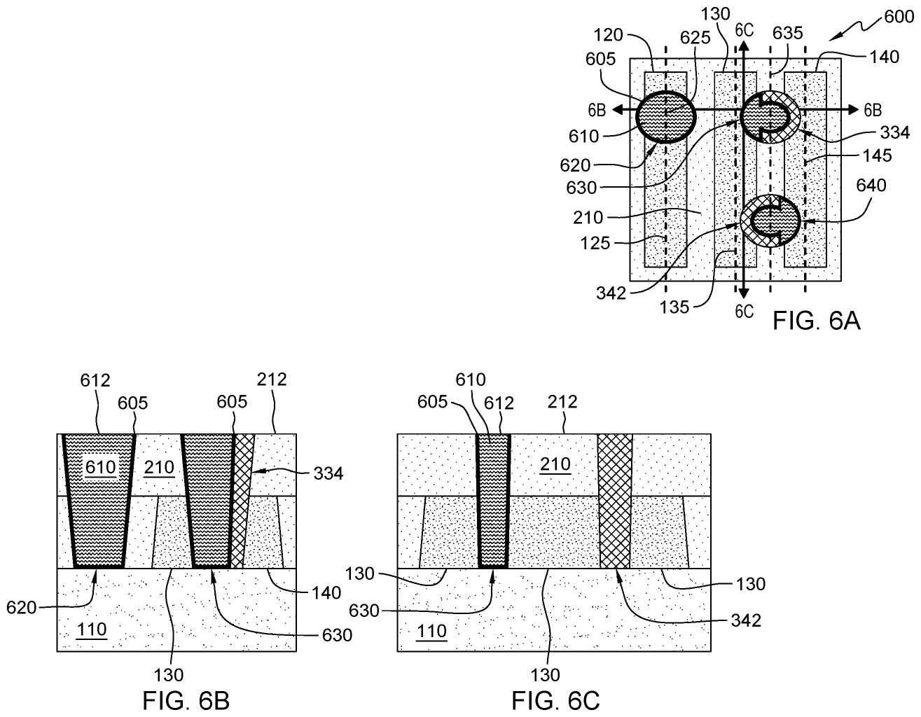

FIGS. 6A-6C illustrate a plan view and corresponding cross-sectional views of semiconductor structure 500 depicted in FIGS. 5A-5C after performing subsequent processing steps, generally designated 600, in accordance with at least one embodiment of the present invention. In assembly of semiconductor structure 600, and referring to the top view of FIG. 6A and the cross-sectional views of FIGS. 6B-6C taken along corresponding lines 6B, 6C, one or more via metallization processes are performed within via openings 220, 230, 240 (depicted in FIGS. 5A-5C) to form vias 620, 630, 640. For example, the one or more via metallization processes may be performed as follows.

An optional metal barrier material is conformally deposited on the exposed surfaces of via openings 220, 230, 240 to form a barrier layer 605. Barrier layer 605 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN) manganese (Mn), manganese nitride (MnN) or other barrier materials (or combinations of barrier materials) such as RuTaN, Ta/TaN, CoWP, NiMoP, or NiMoB which are suitable for the given application. The thin metal barrier serves as a barrier diffusion layer and adhesion layer. A conformal layer of a metal barrier material may be deposited using known techniques including, but not limited to, chemical vapor deposition (CVD), plasma enhanced chemical vapor deposition (PECVD), atomic layer deposition (ALD), physical vapor deposition (PVD), sputtering, chemical solution deposition or plating. The thickness of barrier layer 605 may vary depending on the deposition process used, as well as the material employed.

In some embodiments, an optional plating seed layer (not depicted) can be formed on the metal liner as well. The optional plating seed layer is employed to selectively promote subsequent electroplating of a pre-selected conductive metal or metal alloy. The optional plating seed layer may be composed of Cu, a Cu alloy, Ir, an Ir alloy, Ru, a Ru alloy (e.g., TaRu alloy) or any other suitable noble metal or noble metal alloy having a low metal-plating overpotential. Typically, a Cu or Cu alloy plating seed layer is employed when a Cu metal is to be subsequently formed within the trenches. The optional plating seed layer can be formed by a conventional deposition process including, for example, CVD, PECVD, ALD, or PVD. The thickness of the optional plating seed layer may vary depending on the material of the optional plating seed layer, as well as the technique used in forming the same.

Next, via openings 220, 230, 240 are filled with a conductive metal material 610 until conductive metal material 610 is at least substantially coplanar with top surface 212 of ILD layer 210. In an embodiment, conductive metal material 610 may be a metal or metal alloy including, but not limited to, copper (Cu), aluminum (Al), ruthenium (Ru), rhodium (Rh), iridium (Ir), tungsten (W), molybdenum (Mo), nickel (Ni), or an alloy thereof, such as, for example, a Cu—Al alloy. In those embodiments in which a thin conformal copper (Cu) seed layer (not depicted) is deposited over the surface of barrier layer 605, conductive metal material 610 is subsequently formed within via openings 220, 230, 240 by electroplating of Cu. However, in other embodiments in which a thin conformal copper (Cu) seed layer is not used, conductive metal material 610 can be deposited using a deposition process such as, for example, CVD, PECVD, sputtering, or chemical solution deposition.

In some embodiments, the deposition of conductive metal material 610 is followed by a thermal annealing. For example, the thermal annealing can be a furnace anneal, rapid thermal anneal, flash anneal, or laser anneal. In an embodiment, for furnace anneal and rapid thermal anneal, the annealing temperature can range from 150° C. to 450° C. for furnace anneal and rapid thermal anneal and the anneal duration can range from 10 minutes to one hour. In an embodiment, for flash anneal/laser anneal, the annealing temperature can be higher (e.g., from 450° C. to 1000° C.), but the anneal duration is much shorter (e.g., ranging from 100 nanoseconds to 100 milliseconds).

A planarization process such as, for example, chemical mechanical planarization or polishing (CMP) and/or grinding, may subsequently be performed to remove portions of barrier layer 605, the optional plating seed layer (not depicted), and conductive metal material 610 (collectively referred to as “overburden material”) that is present above top surface 212 of ILD layer 210 to form the final vias 620, 630, 640. The planarization may stop at top surface 212 of ILD layer 210, such that the top surface of barrier layer 605, the top surface of the optional plating seed layer (not depicted), and top surface 612 of conductive metal material 610 are substantially coplanar with top surface 212 of ILD layer 210.

As depicted by FIG. 6A, centerline 625 of via 620 is substantially aligned with centerline 125 of the lower level metal line 120 located beneath via 620. Inner spacer 320 has been completely removed from via 620 since via 620 only comes in contact with a single lower level metal line (i.e., metal line 120). Centerline 635 of vias 630 and 640 is substantially offset from centerlines 135, 145 of lower level metal lines 130, 140. Portion 332 of inner spacer 330 (depicted in FIGS. 4A-4C) has been removed, and portion 334 of inner spacer 330 has been retained. Portion 334 of inner spacer 330 located within via 630 isolates via 630 from contacting the lower level metal line 140, such that via 630 only contacts a single lower level metal line (i.e. metal line 130). Similarly, portion 344 of inner spacer 340 (depicted in FIGS. 4A-4C) has been removed, and portion 342 of inner spacer 340 has been retained. Portion 342 of inner spacer 340 located within via isolates via 640 from contacting the lower level metal line 130, such that via 640 only contacts a single lower level metal line (i.e., metal line 140). It should be appreciated that by retaining a portion of the inner spacer located within a via, the via may be formed substantially offset from a centerline of a lower level metal line, while only contacting a single lower level metal line.

As further depicted by FIGS. 6A-6C, vias 620, 630, 640 are formed completely through lower level metal lines 120, 130, 140, respectively. In some embodiments, although not depicted, vias 620, 630, 640 may further extend at least partially through substrate 110 as well. In some embodiments, although not depicted, vias 620, 630, 640 may only partially extend through metal lines 120, 130, 140, such that top surface 112 of substrate remains covered. In some embodiments, although not depicted, at least one of vias 620, 630, 640 extends completely through one or more underlying metal lines, and at least one of vias 620, 630, 640 extends only partially through one or more underlying metal lines. It should further be appreciated that by forming a via at least partially through a lower level metal line, the via may be formed substantially offset from a centerline of a lower level metal line without any loss of surface contact between the via and the lower level metal line.

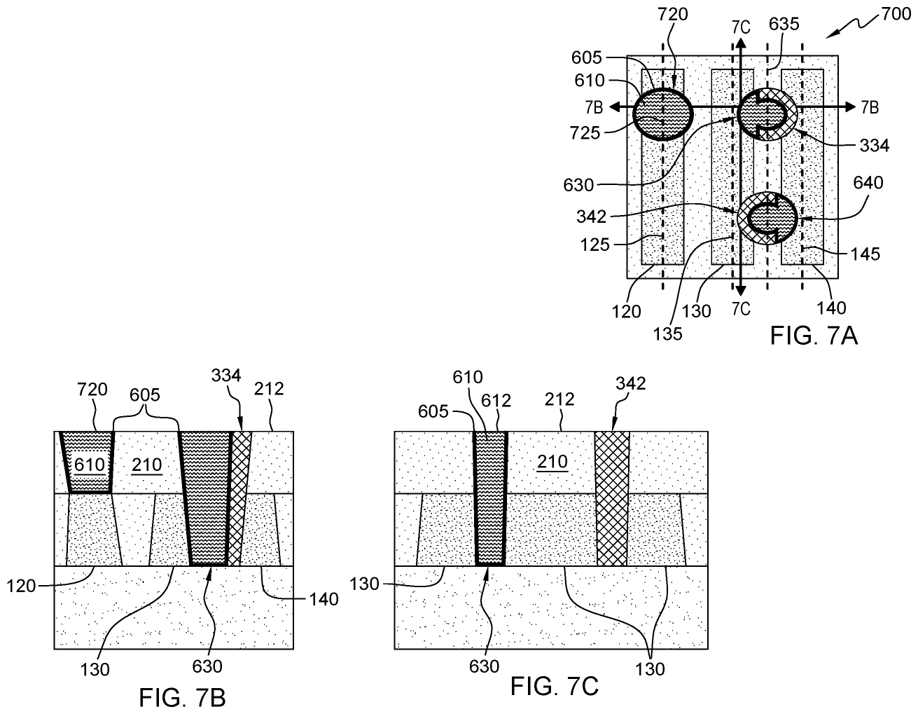

FIGS. 7A-7C illustrate a plan view and corresponding cross-sectional views of an alternate embodiment of semiconductor structure 600 (depicted in FIGS. 6A-6C), generally designated 700, in accordance with at least one embodiment of the present invention. In assembly of semiconductor structure 700, and referring to the top view of FIG. 7A and the cross-sectional views of FIGS. 7B-7C taken along corresponding lines 7B, 7C, rather than forming via 620 (depicted in FIGS. 6A-6C) completely through the lower level metal line 120, via 720 is formed on top of metal line 120. Via 720 may be formed on top of metal line 120 using a single damascene or dual damascene process as known by one of ordinary skill in the art and, as such, a more detailed description of such processes is not presented herein.

As depicted by FIGS. 7A-7C, vias 720, 630 are connected to respective adjacent lower level metal lines 120, 130. However, unlike vias 620, 630 (as depicted in FIGS. 6A-6C), in which both vias 620, 630 are formed completely through metal lines 120, 130, via 720 is now formed on top of lower level metal line 120. This stems from the fact that since centerline 725 of via 720 is substantially aligned with centerline 125 of the lower level metal line 120 located beneath via 720, via 720 only comes in contact with a single lower level metal line (i.e., metal line 120). Similarly, no inner spacer is located within via 720 since via 720 is formed on top of metal line 120 and aligned with the lower metal level line 120. Thus, there is not a need for a spacer to isolate via 720 from contact with a second lower level metal line (e.g., metal line 130) adjacent to line 120.

It should be appreciated that embodiments of the present invention are not limited to the particular arrangement of vias 620, 630 (as depicted in FIGS. 6A-6C) or to the particular arrangement of vias 720, 630 (as depicted in FIGS. 7A-7C). Rather, the foregoing arrangements of vias 620, 630 (as depicted in FIGS. 6A-6C) and vias 720, 630 (as depicted in FIGS. 7A-7C) are presented to illustrate that based on the particular wiring scheme, two vias connected to respective adjacent lower level metal lines need not necessarily both be formed partially and/or completely through the respective adjacent lower level metal lines.

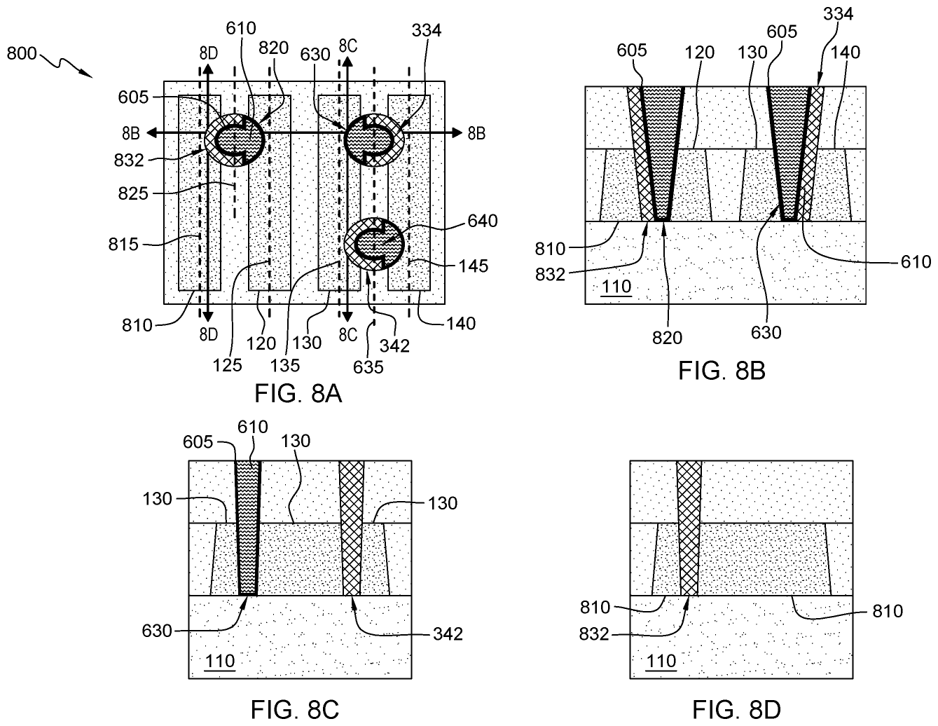

FIGS. 8A-8D illustrate a plan view and corresponding cross-sectional views of an alternate embodiment of semiconductor structure 600 (depicted in FIGS. 6A-6C), generally designated 800, in accordance with at least one embodiment of the present invention. In assembly of semiconductor structure 800, and referring to the top view of FIG. 8A and the cross-sectional views of FIGS. 8B-8D taken along corresponding lines 8B, 8C, 8D, via 620 (depicted in FIGS. 6A-6C) has been replaced by via 820, such that two vias connected to respective adjacent lower level metal lines have centerlines that are vertically offset from the centerlines of the underlying adjacent metal lines.

As depicted by FIG. 8A, via 820 has a centerline 825 that is substantially offset from centerlines 815, 125 of metal lines 810, 120 and is formed completely through respective portions of adjacent lower level metal lines 810, 120. However, due to the particular wiring scheme, via 820 is only electrically connected to metal line 120 since inner spacer 830 insulates via 820 from metal line 810. Via 630 has a centerline 635 that is substantially offset from centerlines 135, 145 of adjacent lower level metal lines 130, 140, and is completely formed through respective portions of adjacent lower level metal lines 130, 140. However, due to the particular wiring scheme, via 630 is only electrically connected to metal line 130 since portion 334 of inner spacer 330 insulates via 630 from metal line 140.

In some embodiments, although not depicted, vias 820, 630, 640 may further extend at least partially through substrate 110 as well. In some embodiments, although not depicted, vias 820, 630, 640 may only partially extend through metal lines 810, 120, 130, 140, such that top surface 112 of substrate remains covered. In some embodiments, although not depicted, at least one of vias 820, 620, 630, 640 extends completely through an underlying metal line, and at least one of vias 820, 620, 630, 640 extends only partially through an underlying metal line.

It should be appreciated that embodiments of the present invention are not limited to the particular arrangement of vias 820, 630, 640 as depicted in FIGS. 8A-8D. Rather, the foregoing arrangement of vias 820, 630, 640 (as depicted in FIGS. 8A-8D) are presented to illustrate that based on the particular wiring scheme, the pitch between two vias connected to respective adjacent lower level metal lines may be further increased by offsetting both vias from the centerlines of the respective underlying adjacent lower level metal lines. Accordingly, by increasing the pitch between the vias, the tip-to-tip (T2T) space between two different upper level metal lines that are connected to the vias and running perpendicular to the lower level adjacent metal lines.

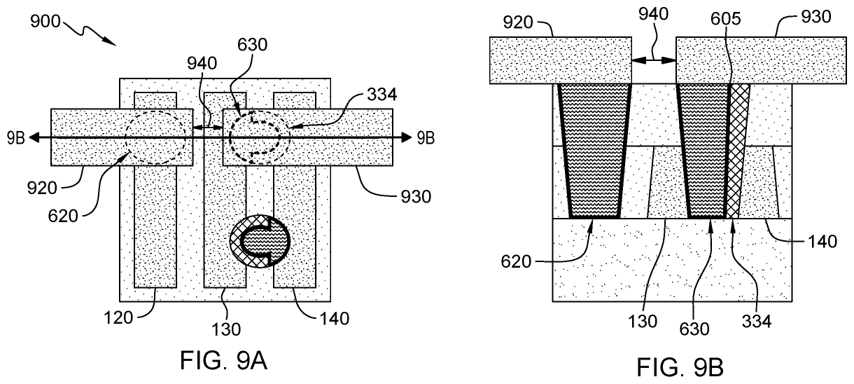

FIGS. 9A-9B illustrate a top view and corresponding cross-sectional view of semiconductor structure 600 after performing subsequent processing steps, generally designated 900, in accordance with at least one embodiment of the present invention. In assembly of semiconductor structure 900, and referring to the top view of FIG. 9A and the cross-sectional view of FIG. 9B taken along corresponding line 9B, upper level metal lines 920, 930 are formed on top of vias 620, 630, respectively. Upper level metal lines 920, 930 may be formed, for example, as part of a single damascene process or dual damascene process as known by one of ordinary skill in the art and, as such, a more detailed description of such processes is not presented herein.

As depicted by FIGS. 9A, 9B, upper level metal line 910 is formed on top of via 620 and runs in a direction that is perpendicular to lower level metal line 120. Upper level metal line 920 is formed on top of via 630 and also runs in a direction that is perpendicular to lower level metal lines 120, 130. Although via 630 is substantially offset from centerline 135 (depicted in FIGS. 6A-6C) of lower level metal line 130, via 630 only contacts a single lower level metal line (i.e., metal line 130) since portion 334 of inner spacer 330 insulates via 630 from lower level metal line 140. It should be appreciated that by offsetting via 630 from centerline 135 of metal line 130, the T2T space 940 between upper level metal lines 920, 930 connected to a pair of adjacent lower level metal lines 120, 130 is increased compared to if via 630 were substantially aligned with centerline 135 lower level metal line 130.

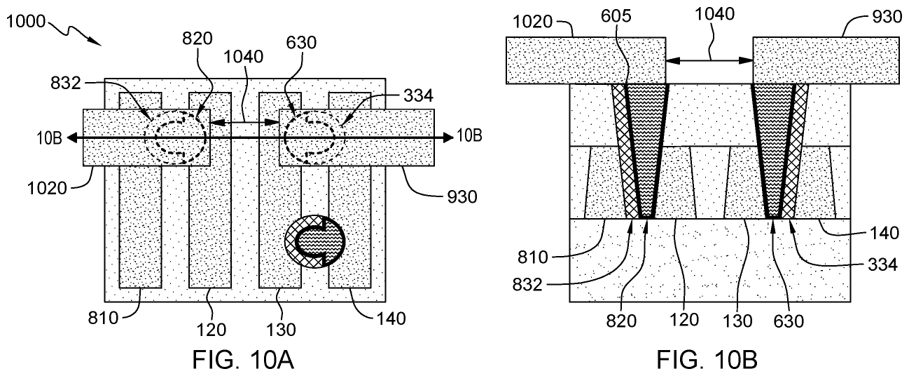

FIGS. 10A, 10B illustrate a top view and corresponding cross-sectional view of semiconductor structure 800 after performing subsequent processing steps, generally designated 1000, in accordance with at least one embodiment of the present invention. In assembly of semiconductor structure 1000, and referring to the top view of FIG. 10A and the cross-sectional view of FIG. 10B taken along corresponding line 10B, upper level metal lines 1020, 930 are formed on top of vias 820, 630, respectively. Upper level metal lines 1020, 930 may be formed, for example, as part of a single damascene process or dual damascene process as known by one of ordinary skill in the art and, as such, a more detailed description of such processes is not presented herein.

As depicted by FIGS. 10A, 10B, upper level metal line 1020 is formed on top of via 820 and runs in a direction that is perpendicular to lower level metal lines 810, 120. Although via 820 is substantially offset from centerline 125 of lower level metal line 810, via 820 only contacts a single lower level metal line (i.e., metal line 120) since inner spacer 832 insulates via 820 from lower level metal line 810. Upper level metal line 930 is formed on top of via 630 and also runs in a direction that is perpendicular to lower level metal lines 130, 140. Although via 630 is substantially offset from centerline 135 (depicted in FIGS. 6A-6C) of lower level metal line 130, via 630 only contacts a single lower level metal line (i.e., metal line 130) since portion 334 of inner spacer 330 insulates via 630 from lower level metal line 140. It should be appreciated that by offsetting both via 820 from centerline 125 of metal line 120 and via 630 from centerline 135 of metal line 130, the T2T space 1040 between upper level metal lines 1020, 930 connected to a pair of adjacent lower level metal lines 120, 130 is increased even further compared to if only one of vias 820, 630 were offset.

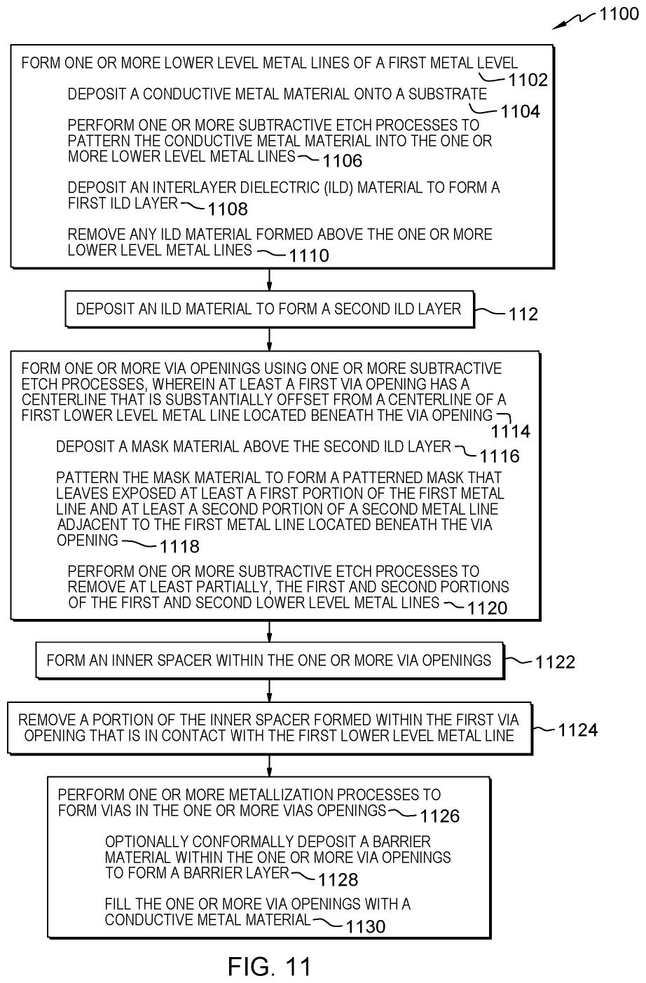

FIG. 11 is a method of fabricating a semiconductor interconnect structure, generally designated 1100, in accordance with at least one embodiment of the present invention. The method 1100 may be used in conjunction with other embodiments, for example, any of the exemplary fabrication sequences of FIGS. 1A-1C . . . FIGS. 7A-7C, FIGS. 8A-8D, FIGS. 9A, 9B, and FIGS. 10A, 10B.

The method optionally begins at block 1102, where one or more lower level metal lines of a first metal level are arranged above a substrate. In some embodiments, forming the one or lower level metal lines comprises (at block 1104) depositing a conductive metal material onto the substrate, (at block 1106) performing one or more subtractive etch processes to pattern the conductive metal material into the one or more metal lines, (at block 1108) forming a first interlayer dielectric (ILD) layer by depositing an ILD material onto the substrate and patterned conductive metal layer, and (at block 1110) removing any ILD material formed above the one or more metal lines. In some embodiments, the first ILD layer has a top surface that is substantially coplanar with the top surface(s) of the one or more metal lines.

Alternatively, forming the one or more lower level metal lines of the first metal level comprises depositing an interlayer dielectric (ILD) material onto the substrate to form an ILD layer, patterning the ILD layer to form one or more trenches, and backfilling the one or more trenches with a conductive metal material.

At block 1112, a second (ILD) is formed by depositing an ILD material onto the top surface(s) of the first ILD layer and the one or more metal lines.

At block 1114, one or more via openings are formed using one or more subtractive etch processes. In some embodiments, at least a first via opening has a centerline that is substantially offset from a centerline of a first lower level metal line located beneath the via opening. In some embodiments, forming the one or more via openings comprises (at block 1116) depositing a mask material above the second ILD layer, (at block 1118) patterning the mask material to form a patterned mask that leaves exposed at least a first portion of the first metal line and at least a second portion of a second metal line adjacent to the first metal line and also located beneath the first via opening, and (at block 1120) performing one or more subtractive etch processes using the patterned mask to remove, at least partially, the first and second portions of the first and second lower level metal lines. In some embodiments, the first and second portions of the first and second lower level metal lines are completely removed.

At block 1122, an inner spacer is formed within the one or more via openings. At block 1124, a portion of the inner spacer formed within the at least first via opening that is in contact with the first metal line is removed.

At block 1126, one or more metallization processes are performed to form a first via in the at least first via opening, such that the first via is only in contact with the first metal line. In some embodiments, performing the one or more metallization processes comprises (at block 1128) optionally conformally depositing a barrier material within at least the first via opening to form a barrier layer, and (at block 11) filling at least the first via opening with a conductive metal material to form the first via, such that a remaining portion of the inner spacer insulates the first via from contacting the second metal line.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

What is claimed is:

1. A semiconductor interconnect structure, comprising:
a plurality of metal lines of a first metal level; and
a via formed substantially offset from a centerline of a first metal line and at least partially through a first portion of the first metal line located beneath the via.

2. The semiconductor interconnect structure of claim 1, wherein the via is further formed at least partially through a second portion of a second metal line located adjacent to the first metal line.

3. The semiconductor interconnect structure of claim 2, wherein the via further includes an inner spacer formed within a portion of the via that isolates the via from contacting the second metal line.

4. The semiconductor interconnect structure of claim 1, wherein the via is formed completely through the first portion of the first metal line and completely through a second portion of a second metal line located adjacent to the first metal line.

5. The semiconductor interconnect structure of claim 1, wherein the via is further formed completely through a second portion of a second metal line located adjacent to the first metal line.

6. A semiconductor interconnect structure, comprising:
a plurality of metal lines of a first metal level;
a first via formed substantially over a centerline of a first metal line of the plurality of metal lines located beneath the first via; and
a second via formed substantially offset from a centerline of a second metal line of the plurality of metal lines located beneath the second via.

7. The semiconductor interconnect structure of claim 1, wherein the first metal line is located adjacent to the second metal line.

8. The semiconductor interconnect structure of claim 1, wherein:
the first via is formed on top of the first metal line; and
the second via is formed at least partially through a portion of the second metal line.

9. The semiconductor interconnect structure of claim 1, wherein:
the first via is formed at least partially through a first portion of the first metal line; and
the second via is formed at least partially through a second portion of the second metal line.

10. The semiconductor interconnect structure of claim 1, wherein:
the first via is formed completely through a first portion of the first metal line; and
the second via is formed completely through a second portion of the second metal line.

11. The semiconductor interconnect structure of claim 1, wherein the second via further includes an inner spacer formed within a portion of the second via.

12. The semiconductor interconnect structure of claim 11, wherein the inner spacer formed within the portion of the second via isolates the second via from contacting a third metal line of the plurality of metal lines located beneath the second via and adjacent to the second metal line.

13. A semiconductor interconnect structure, comprising:
a plurality of metal lines of a first metal wiring level;
a first via formed substantially offset from a centerline of a first metal line of the plurality of metal lines located beneath the first via; and
a second via formed substantially offset from a centerline of a second metal line of the plurality of metal lines located beneath the second via.

14. The semiconductor interconnect structure of claim 9, wherein the first via and the second via at least partially aligned with each other along a line direction of the plurality of metal lines of the first metal level.

15. The semiconductor interconnect structure of claim 9, wherein the first metal line is located adjacent to the second metal line.

16. The semiconductor interconnect structure of claim 1, wherein:
the first via is formed at least partially through the first metal line; and
the second via is formed at least partially through the second metal line.

17. The semiconductor interconnect structure of claim 13, wherein:
the first via is formed at least partially through a first portion of the first metal line; and
the second via is formed at least partially through a second portion of the second metal line.

18. The semiconductor interconnect structure of claim 13, wherein:
the first via is formed completely through a first portion of the first metal line; and
the second via is formed completely through a second portion of the second metal line.

19. The semiconductor interconnect structure of claim 1, wherein:
the first via further includes a first inner spacer formed along a portion of a sidewall of the first via; and
the second via further includes a second inner spacer formed along a portion of a sidewall of the second via.

20. The semiconductor interconnect structure of claim 12, wherein:
the first inner spacer formed along the portion of the sidewall of the first via isolates the second via from a third metal line of the plurality of metal lines located beneath the first via and adjacent to the second metal line; and
the second inner spacer formed along the portion of the sidewall of the second via isolated the second via from a fourth metal line of the plurality of metal lines located beneath the second via and adjacent to the first metal line.
